(19) United States
(12) Patent Application Publication
(10) Pub. No.: US 2024/0304510 A1
(43) Pub. Date: Sep. 12, 2024

(54) SEMICONDUCTOR DEVICE

(71) Applicant: Rohm Co., Ltd., Kyoto-shi (JP)

(72) Inventors: Hiroaki MATSUBARA, Kyoto-shi (JP); Taro NISHIOKA, Kyoto-shi (JP); Yoshizo OSUMI, Kyoto-shi (JP)

(21) Appl. No.: 18/660,967

(22) Filed: May 10, 2024

Related U.S. Application Data
(63) Continuation of application No. PCT/JP2022/043014, filed on Nov. 21, 2022.

(30) Foreign Application Priority Data
Nov. 25, 2021 (JP) 2021-191493

(51) Int. Cl. H01L 23/31; H01L 23/00; H01L 23/29; H01L 23/498; H01L 23/522; H01L 25/18

(52) U.S. Cl. CPC H01L 23/3135; H01L 23/291; H01L 23/49838; H01L 23/5223; H01L 23/5227; H01L 24/48; H01L 24/49; H01L 25/18; H01L 2224/48137; H01L 2224/48247; H01L 2224/49175; H01L 2924/1815

(57) ABSTRACT

A semiconductor device includes: a first semiconductor element; a second semiconductor element; an insulating element electrically connected to the first semiconductor element and the second semiconductor element, and insulating the first semiconductor element and the second semiconductor element from each other; and a sealing resin covering the first semiconductor element, the second semiconductor element, and the insulating element. The sealing resin includes a first portion covering the first semiconductor element, the second semiconductor element, and the insulating element, and a second portion constituting the outermost surface of the sealing resin. The second portion is less prone to a tracking phenomenon than the first portion.

### TECHNICAL FIELD

The present disclosure relates to a semiconductor device.

### BACKGROUND ART

Inverters used in electric vehicles (including hybrid vehicles) and home appliances include semiconductor devices. For example, an inverter includes a semiconductor device and a switching element such as an insulated gate bipolar transistor (IGBT) or a metal oxide semiconductor field effect transistor (MOSFET). The semiconductor device includes a controller and a gate driver. In the inverter, a control signal outputted from an external source is inputted to the controller of the semiconductor device. The controller converts the control signal into a pulse width modulation (PWM) control signal and transmits the PWM control signal to the gate driver. The gate driver drives, for example, six switching elements at a desired timing based on the PWM control signal. As a result, three-phase AC power for motor driving is generated from DC power. JP-A-2020-167428 discloses an example of a semiconductor device (drive circuit) used for a motor driving device.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, with a sealing resin shown transparent.

FIG. 3 is a front view showing the semiconductor device in FIG. 1.

FIG. 4 is a left-side view showing the semiconductor device in FIG. 1.

FIG. 5 is a right-side view showing the semiconductor device in FIG. 1.

FIG. 6 is a cross-sectional view along line VI-VI in FIG. 2.

FIG. 7 is a cross-sectional view along line VII-VII in FIG. 2.

FIG. 8 is an enlarged cross-sectional view of a main part of the semiconductor device in FIG. 1.

FIG. 9 is a cross-sectional view showing a first variation of the semiconductor device according to the first embodiment of the present disclosure.

FIG. 10 is a cross-sectional view showing a second variation of the semiconductor device according to the first embodiment of the present disclosure.

FIG. 11 is a plan view showing a semiconductor device according to a second embodiment of the present disclosure.

FIG. 12 is a cross-sectional view along line XII-XII in FIG. 11.

FIG. 13 is a plan view showing a semiconductor device according to a third embodiment of the present disclosure.

FIG. 14 is a cross-sectional view along line XIV-XIV in FIG. 13.

FIG. 15 is a plan view showing a semiconductor device according to a fourth embodiment of the present disclosure.

FIG. 16 is a cross-sectional view along line XVI-XVI in FIG. 15.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the items to which these terms refer.

### First Embodiment

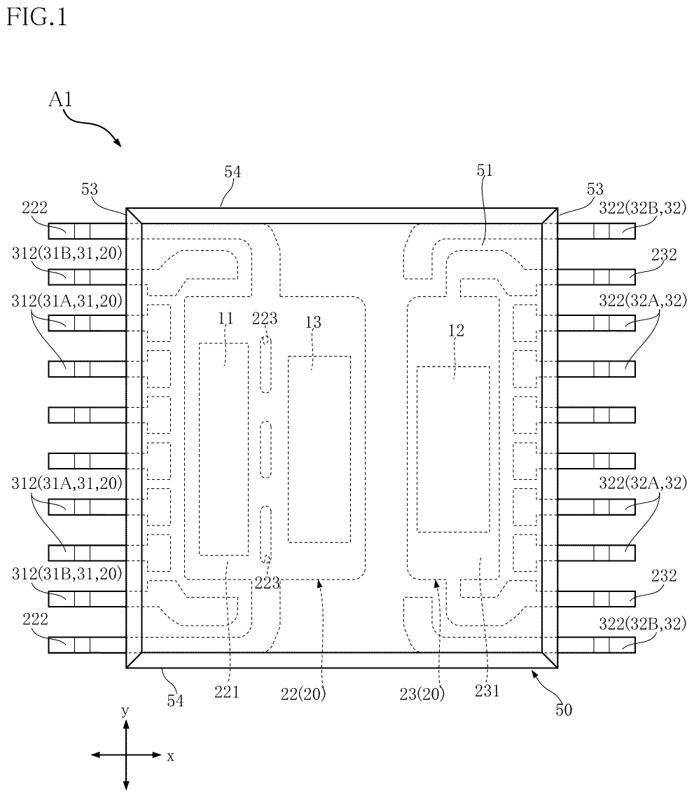

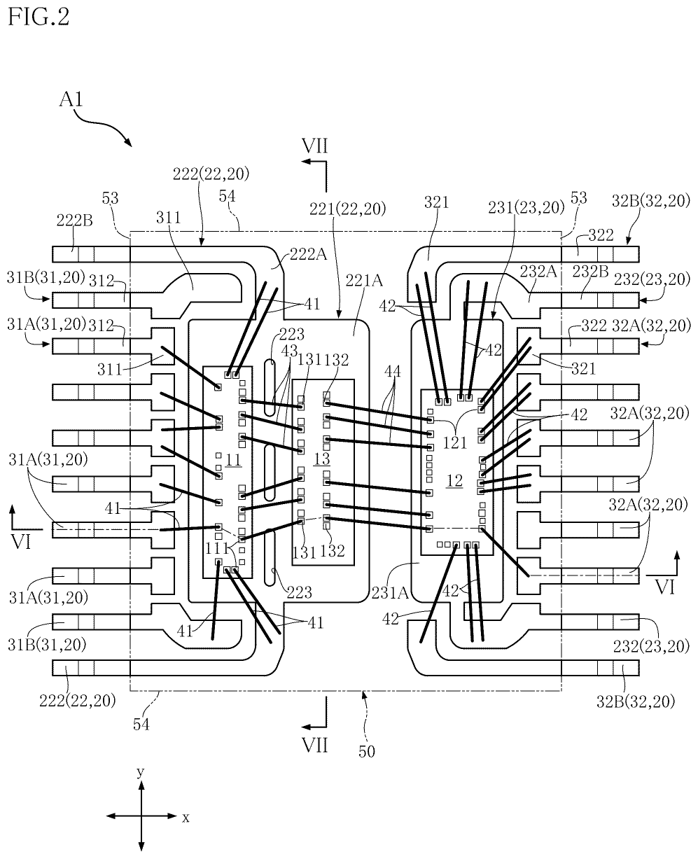

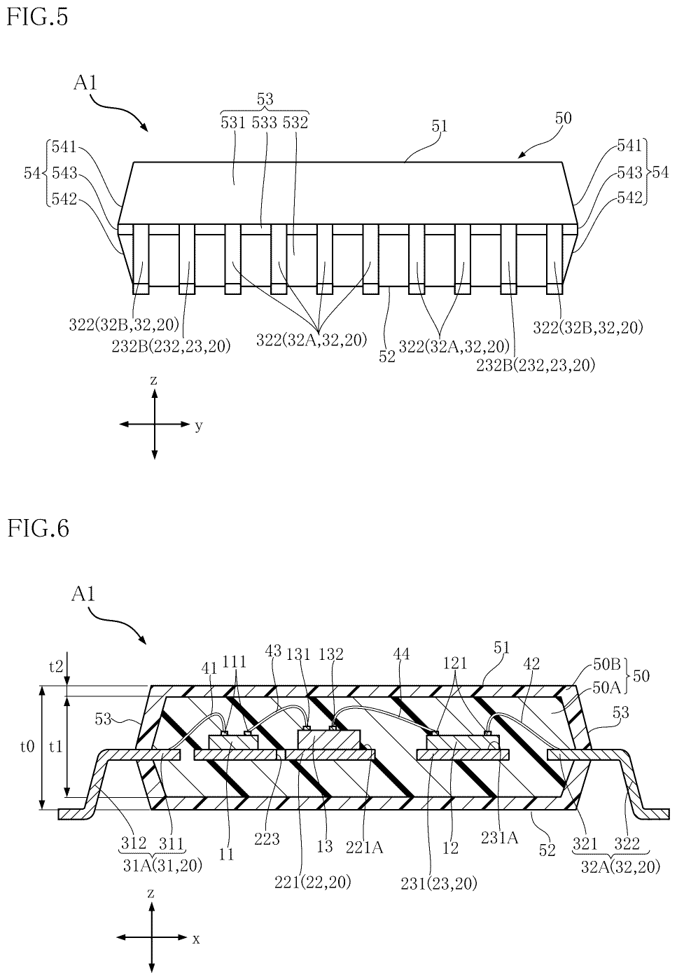

The following describes a semiconductor device A1 according to a first embodiment of the present disclosure, with reference to FIGS. 1 to 8. The semiconductor device A1 includes a first semiconductor element 11, a second semiconductor element 12, an element a insulating 13, plurality of conductive members 20, a plurality of first wires 41, a plurality of second wires 42, a plurality of third wires 43, a plurality of fourth wires 44, and a sealing resin 50. The semiconductor device A1 is surface-mounted on a wiring board of an inverter for an electric vehicle or a hybrid vehicle, for example. The semiconductor device A1 is provided in a small outline package (SOP). Note that the package type of the semiconductor device A1 is not limited to an SOP. In FIG. 2, the sealing resin 50 is shown in phantom for convenience of understanding, and is indicated by an imaginary line (two-dot chain line).

As one example, in the description of the semiconductor device A1, the thickness direction of each of the first semiconductor element 11, the second semiconductor element 12, and the insulating element 13 is referred to as “thickness direction z”. A direction perpendicular to the thickness direction z is referred to as “first direction x”. The direction perpendicular to both of the thickness direction z and the first direction x is referred to as “second direction y”.

The first element semiconductor 11, the second semiconductor element 12, and the insulating element 13 form the functional core of the semiconductor device A1. In the semiconductor device A1, each of the first semiconductor element 11, the second semiconductor element 12, and the insulating element 13 is an individual element. In the first direction x, the second semiconductor element 12 is located opposite from the first semiconductor element 11 with respect to the insulating element 13. In other words, the insulating element 13 is located between the first semiconductor element 11 and the second semiconductor element 12 in the first direction x. As viewed in the thickness direction z, each of the first semiconductor element 11, the second semiconductor element 12, and the insulating element 13 has a rectangular shape elongated in the second direction y.

The first semiconductor element 11 is a controller (control element) of a gate driver for driving a switching element such as an IGBT or a MOSFET. The first semiconductor element 11 has a circuit that converts a control signal inputted from, for example, an ECU into a PWM control signal, a transmission circuit that transmits the PWM control signal to the second semiconductor element 12, and a reception circuit that receives an electric signal from the second semiconductor element 12.

The second semiconductor element 12 is a gate driver (drive element) for driving a switching element. The second semiconductor element 12 has a reception circuit that receives a PWM control signal, a drive circuit that drives the switching element based on the PWM control signal, and a transmission circuit that transmits an electric signal to the first semiconductor element 11. The electric signal may be an output signal from a temperature sensor located near a motor.

The insulating element 13 transmits a PWM control signal or other electric signals in an electrically insulated state. In the semiconductor device A1, the insulating element 13 is of an inductive type. An example of the inductive insulating element 13 is an insulating transformer. The insulating transformer transmits an electric signal in an electrically insulated state by inductively coupling two inductors (coils). The insulating element 13 has a silicon substrate. Inductors made of copper (Cu) are mounted on the substrate. The inductors include a transmission inductor and a reception inductor, which are stacked in the thickness direction z. A dielectric layer made of, for example, silicon dioxide (SiO₂) is provided between the transmission inductor and the reception inductor. The dielectric layer electrically insulates the transmission inductor from the reception inductor. Alternatively, the insulating element 13 may be of a capacitive type. An example of the capacitive insulating element 13 is a capacitor.

In the semiconductor device A1, the voltage applied to the first semiconductor element 11 is different from the voltage applied to the second semiconductor element 12. As a result, a potential difference is created between the first semiconductor element 11 and the second semiconductor element 12. Furthermore, in the semiconductor device A1, the source voltage supplied to the second semiconductor element 12 is higher than the source voltage supplied to the first semiconductor element 11.

In the semiconductor device A1, a first circuit including the first semiconductor element 11 as a component and a second circuit including the second semiconductor element 12 as a component are insulated from each other by the insulating element 13. The insulating element 13 is electrically connected to the first circuit and the second circuit. The first circuit further includes a first die pad 22 (described below), a plurality of first terminals 31 (described below), the first wires 41, and the third wires 43, in addition to the first semiconductor element 11. The second circuit further includes a second die pad 23 (described below), a plurality of second terminals 32 (described below), the second wires 42, and the fourth wires 44, in addition to the second semiconductor element 12. The first circuit has a different potential from the second circuit. In the semiconductor device A1, the second circuit has a higher potential than the first circuit. As such, the insulating element 13 relays a mutual signal between the first circuit and the second circuit. In the case of an inverter for an electric vehicle or a hybrid vehicle, the voltage applied to the ground of the first semiconductor element 11 is approximately 0 V, whereas the voltage applied to the ground of the second semiconductor element 12 becomes 600 V or higher transiently.

As shown in FIGS. 2 and 6, the first semiconductor element 11 has a plurality of first electrodes 111. The first electrodes 111 are provided on an upper surface of the first semiconductor element 11 (i.e., a surface facing in the same direction as a first mounting surface 221A of a first pad portion 221 of the first die pad 22 described below). The composition of the first electrodes 111 includes aluminum (Al), for example. In other words, each of the first electrodes 111 contains aluminum. The first electrodes 111 are electrically connected to the circuit configured in the first semiconductor element 11.

As shown in FIGS. 2 and 6, the insulating element 13 is located between the first semiconductor element 11 and the second semiconductor element 12 in the first direction x. As shown in FIGS. 8 and 9, the insulating element 13 has a plurality of first relay electrodes 131 and a plurality of second relay electrodes 132. The first relay electrodes 131 and the second relay electrodes 132 are provided on an upper surface of the insulating element 13 (i.e., a surface facing in the same direction as the first mounting surface 221A described above). The first relay electrodes 131 are aligned in the second direction y, and are located closer to the first semiconductor element 11 than to the second semiconductor element 12 in the first direction x. The second relay electrodes 132 are aligned in the second direction y, and are located closer to the second semiconductor element 12 than to the first semiconductor element 11 in the first direction x.

As shown in FIGS. 2 and 6, the second semiconductor element 12 has a plurality of second electrodes 121. The second electrodes 121 are provided on an upper surface of the second semiconductor element 12 (i.e., a surface facing in the same direction as a second mounting surface 231A of a second pad portion 231 of the second die pad 23 described below). The composition of the second electrodes 121 includes aluminum, for example. The second electrodes 121 are electrically connected to the circuit configured in the second semiconductor element 12.

The conductive members 20 form a conductive path between a wiring board on which the semiconductor device A1 is mounted and each of the first semiconductor element 11, the insulating element 13, and the second semiconductor element 12. The conductive members 20 are formed from the same lead frame. The lead frame contains copper in its composition. As described above, the conductive members 20 include the first die pad 22, the second die pad 23, the first terminals 31, and the second terminals 32.

As shown in FIGS. 1 and 2, the first die pad 22 and the second die pad 23 are spaced apart from each other in the first direction x. In the semiconductor device A1, the first semiconductor element 11 and an insulating element 13 are bonded to the first die pad 22, and the second semiconductor element 12 is bonded to the second die pad 23. The voltage applied to the second die pad 23 is different from the voltage applied to the first die pad 22. In the semiconductor device A1, the voltage applied to the second die pad 23 is higher than the voltage applied to the first die pad 22.

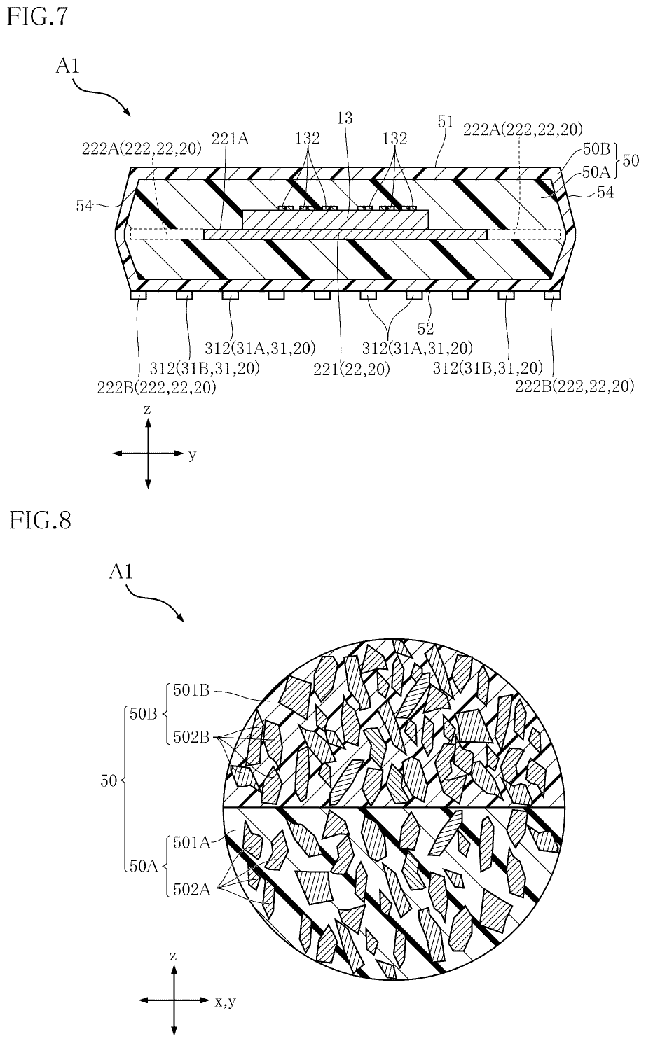

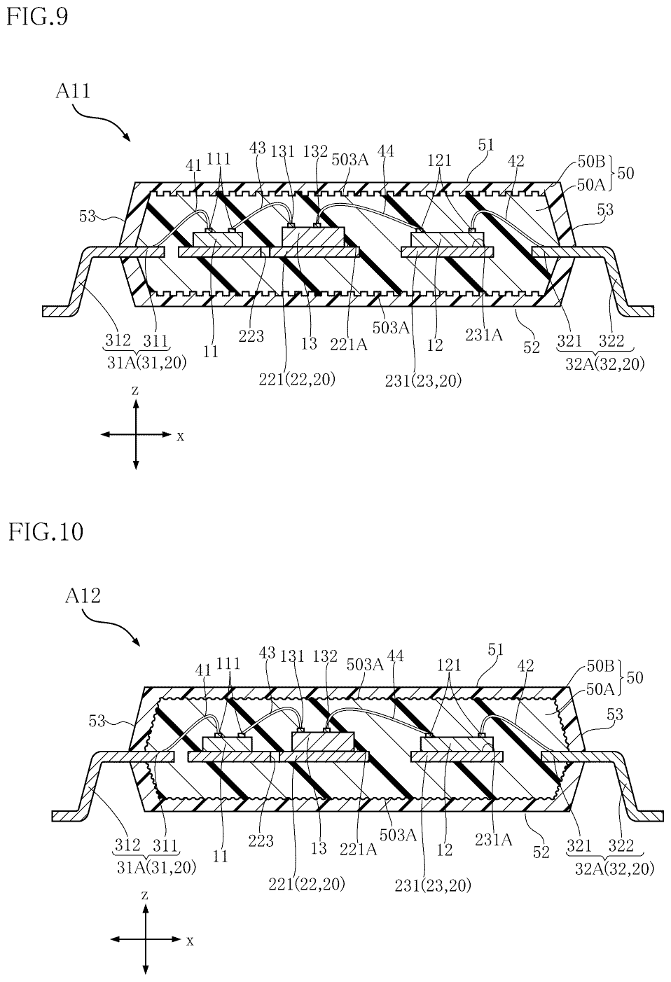

As shown in FIG. 2, the first die pad 22 has a first pad portion 221 and two first suspending lead portions 222. The first semiconductor element 11 is located on the first pad portion 221. As shown in FIGS. 6 and 7, the first pad portion 221 has a first mounting surface 221A facing in the thickness direction z. The first semiconductor element 11 is bonded to the first mounting surface 221A via a non-illustrated conductive bonding member (e.g., solder or metal paste). The first pad portion 221 is covered with the sealing resin 50. The first pad portion 221 has a thickness of about 150 μm to 200 μm, for example.

As shown in FIGS. 2 and 6, the first pad portion 221 is formed with a plurality of through-holes 223. The through-holes 223 pass through the first pad portion 221 in the thickness direction z and extend in the second direction y. As viewed in the thickness direction z, at least one of the through-holes 223 is located between the first semiconductor element 11 and the insulating element 13. The through-holes 223 are aligned in the second direction y.

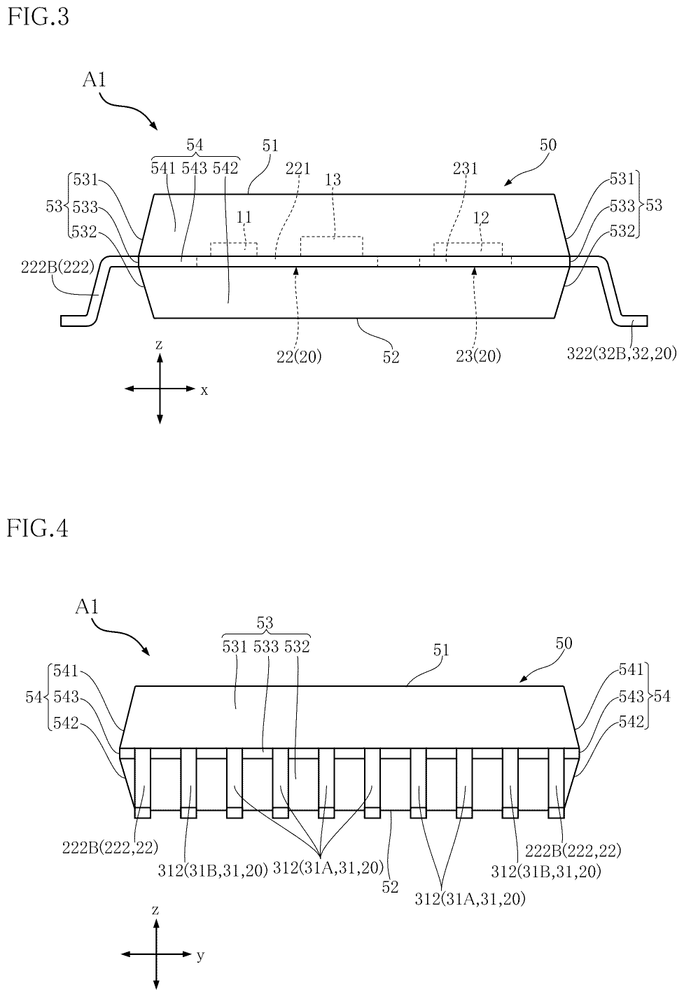

As shown in FIG. 2, the two first suspending lead portions 222 are connected to the respective sides of the first pad portion 221 in the second direction y. Each of the first suspending lead portions 222 has a covered portion 222A and an exposed portion 222B. The covered portion 222A is connected to the first pad portion 221 and covered with the sealing resin 50. The covered portion 222A includes a section extending in the first direction x. The exposed portion 222B is connected to the covered portion 222A and exposed from the sealing resin 50. As viewed in the thickness direction z, the exposed portion 222B extends in the first direction x. As shown in FIG. 3, the exposed portion 222B is bent into a gull-wing shape as viewed in the second direction y. The surface of the exposed portion 222B may be plated with tin (Sn), for example.

As shown in FIG. 2, the second die pad 23 has a second pad portion 231 and two second suspending lead portions 232. The second semiconductor element 12 is located on the second pad portion 231. As shown in FIG. 6, the second pad portion 231 has a second mounting surface 231A facing in the thickness direction z. The second semiconductor element 12 is bonded to the second mounting surface 231A via a non-illustrated conductive bonding member (e.g., solder or metal paste). The second pad portion 231 is covered with the sealing resin 50. The second pad portion 231 has a thickness of about 150 μm to 200 μm, for example. The area of the second pad portion 231 is smaller than the area of the first pad portion 221 of the first die pad 22. As viewed in the first direction x, the second pad portion 231 overlaps with the first pad portion 221.

As shown in FIG. 2, the two second suspending lead portions 232 extend from the respective sides of the second pad portion 231 in the second direction y. Each of the two second suspending lead portions 232 has a covered portion 232A and an exposed portion 232B. The covered portion 232A is connected to the second pad portion 231 and covered with the sealing resin 50. The covered portion 232A includes a section extending in the first direction x. The exposed portion 232B is connected to the covered portion 232A and exposed from the sealing resin 50. As viewed in the thickness direction z, the exposed portion 232B extends in the first direction x. As shown in FIG. 3, the exposed portion 232B is bent into a gull-wing shape as viewed in the second direction y. The surface of the exposed portion 232B may be plated with tin (Sn), for example.

As shown in FIGS. 1 and 2, the first terminals 31 are located on a first side in the first direction x. More specifically, the first terminals 31 are located opposite from the second pad portion 231 of the second die pad 23 with respect to the first pad portion 221 of the first die pad 22 in the first direction x. The first terminals 31 are aligned in the second direction y. At least one of the first terminals 31 is electrically connected to the first semiconductor element 11 via a first wire 41. The first terminals 31 include a plurality of first inner terminals 31A and two first outer terminals 31B. The two first outer terminals 31B flank the first inner terminals 31A in the second direction y. In the second direction y, each of the two first outer terminals 31B is located between one of the two first suspending lead portions 222 of the first die pad 22 and the first inner terminal 31A closest to the first suspending lead portion 222.

As shown in FIGS. 2 and 6, each of the first terminals 31 has a covered portion 311 and an exposed portion 312. The covered portion 311 is covered with the sealing resin 50. The covered portion 311 of each of the two first outer terminals 31B is larger in dimension than the covered portion 311 of each of the first inner terminals 31A in the first direction x.

As shown in FIGS. 2 and 6, the exposed portion 312 is connected to the covered portion 311, and is exposed from the sealing resin 50. As viewed in the thickness direction z, the exposed portion 312 extends in the first direction x. The exposed portion 312 is bent into a gull-wing shape as viewed in the second direction y. The exposed portion 312 has the same shape as the exposed portion 222B of each of the two first suspending lead portions 222 of the first die pad 22. The surface of the exposed portion 312 may be plated with tin, for example.

As shown in FIGS. 1 and 2, the second terminals 32 are located on a second side in the first direction x. More specifically, the second terminals 32 are located opposite from the first terminals 31 with respect to the first pad portion 221 of the first die pad 22 in the first direction x. The second terminals 32 are aligned in the second direction y. At least one of the second terminals 32 is electrically connected to the second semiconductor element 12 via a second wire 42. The second terminals 32 include a plurality of second inner terminals 32A and two second outer terminals 32B. The two second outer terminals 32B flank the second inner terminals 32A in the second direction y. In the second direction y, each of the two second suspending lead portions 232 of the second die pad 23 is located between one of the two second outer terminals 32B and the second inner terminal 32A closest to the second outer terminal 32B.

As shown in FIGS. 2 and 6, each of the second terminals 32 has a covered portion 321 and an exposed portion 322. The covered portion 321 is covered with the sealing resin 50. The covered portion 321 of each of the two second outer terminals 32B is larger in dimension than the covered portion 321 of each of the second inner terminals 32A in the first direction x.

As shown in FIGS. 2 and 6, the exposed portion 322 is connected to the covered portion 321, and is exposed from the sealing resin 50. As viewed in the thickness direction z, the exposed portion 322 extends in the first direction x. As shown in FIG. 3, the exposed portion 322 is bent into a gull-wing shape as viewed in the second direction y. The exposed portion 322 has the same shape as the exposed portion 232B of each of the two second suspending lead portions 232 of the second die pad 23. The surface of the exposed portion 322 may be plated with tin (Sn), for example.

The first wires 41, the second wires 42, the third wires 43, and the fourth wires 44, as well as the conductive members 20, form a conductive path for the first semiconductor element 11, the second semiconductor element 12, and the insulating element 13 to perform predetermined functions.

As shown in FIGS. 2 and 6, some of the first wires 41 are bonded to some first electrodes 111 of the first semiconductor element 11 and the covered portions 311 of some first terminals 31. As a result, at least one of the first terminals 31 is electrically connected to the first semiconductor element 11. Furthermore, at least one of the first wires 41 is bonded to one of the first electrodes 111 and one of the covered portions 222A of the two first suspending lead portions 222 of the first die pad 22. As a result, at least one of the two first suspending lead portions 222 is electrically connected to the first semiconductor element 11. As such, at least one of the two first suspending lead portions 222 forms a ground terminal of the first semiconductor element 11. The composition of the first wires 41 includes gold (Au). Alternatively, the composition of the first wires 41 may include copper (Cu).

As shown in FIGS. 2 and 6, some of the second wires 42 are bonded to some second electrodes 121 of the second semiconductor element 12 and the covered portions 321 of some second terminals 32. As a result, at least one of the second terminals 32 is electrically connected to the second semiconductor element 12. Furthermore, at least one of the second wires 42 is bonded to one of the second electrodes 121 and one of the covered portions 232A of the two second suspending lead portions 232 of the second die pad 23. As a result, at least one of the two second suspending lead portions 232 is electrically connected to the second semiconductor element 12. As such, at least one of the two second suspending lead portions 232 forms a ground terminal of the second semiconductor element 12. The composition of the second wires 42 includes gold (Au). Alternatively, the composition of the second wires 42 may include copper (Cu).

As shown in FIGS. 2 and 6, the third wires 43 are bonded to some first relay electrodes 131 of the insulating element 13 and some first electrodes 111 of the first semiconductor element 11. As a result, the first semiconductor element 11 and the insulating element 13 are electrically connected to each other. The third wires 43 are aligned in the second direction y. The composition of the third wires 43 includes gold (Au).

As shown in FIGS. 2 and 6, the fourth wires 44 are bonded to some second relay electrodes 132 of the insulating element 13 and some second electrodes 121 of the second semiconductor element 12. As a result, the second semiconductor element 12 and the insulating element 13 are electrically connected to each other. The fourth wires 44 are aligned in the second direction y. In the semiconductor device A1, the fourth wires 44 extend across the first pad portion 221 of the first die pad 22 and the second pad portion 231 of the second die pad 23. The composition of the fourth wires 44 includes gold (Au).

As shown in FIG. 1, the sealing resin 50 covers the first semiconductor element 11, the second semiconductor element 12, the insulating element 13, and at least a portion of each of the conductive members 20. Furthermore, the sealing resin 50 covers the first wires 41, the second wires 42, the third wires 43, and the fourth wires 44. The sealing resin 50 is electrically insulative. The shape of the sealing resin 50 is not particularly limited. For example, the sealing resin 50 may have a rectangular shape as viewed in the thickness direction z.

As shown in FIGS. 3 to 5, the sealing resin 50 has a top surface 51, a bottom surface 52, a pair of first side surfaces 53, and a pair of second side surfaces 54.

As shown in FIGS. 3 to 5, the top surface 51 and the bottom surface 52 are spaced apart from each other in the thickness direction z. The top surface 51 and the bottom surface 52 face away from each other in the thickness direction z. Each of the top surface 51 and the bottom surface 52 is flat (or substantially flat).

As shown in FIGS. 3 to 5, the pair of first side surfaces 53 are connected to the top surface 51 and the bottom surface 52, and are spaced apart from each other in the first direction x. The exposed portions 222B of the two first suspending lead portions 222 of the first die pad 22 and the exposed portions 312 of the first terminals 31 are exposed from one of the pair of first side surfaces 53 that is located on the first side in the first direction x. The exposed portions 222B of the two second suspending lead portions 232 of the second die pad 23 and the exposed portions 322 of the second terminals 32 are exposed from one of the first side surfaces 53 that is located on the second side in the first direction x.

As shown in FIGS. 3 to 5, each of the pair of first side surfaces 53 includes a first upper portion 531, a first lower portion 532, and a first intermediate portion 533. One end of the first upper portion 531 in the thickness direction z is connected to the top surface 51, and the other end thereof in the thickness direction z is connected to the first intermediate portion 533. The first upper portion 531 is inclined relative to the top surface 51. One end of the first lower portion 532 in the thickness direction z is connected to the bottom surface 52, and the other end thereof in the thickness direction z is connected to the first intermediate portion 533. The first lower portion 532 is inclined relative to the bottom surface 52. One end of the first intermediate portion 533 in the thickness direction z is connected to the first upper portion 531, and the other end thereof in the thickness direction z is connected to the first lower portion 532. The in-plane direction of the first intermediate portion 533 is defined by the thickness direction z and the second direction y. As viewed in the thickness direction z, the first intermediate portion 533 is located more outward than the top surface 51 and the bottom surface 52. The exposed portions 222B of the two first suspending lead portions 222 of the first die pad 22, the exposed portions 222B of the two second suspending lead portions 232 of the second die pad 23, the exposed portions 312 of the first terminals 31, and the exposed portions 322 of the second terminals 32 are exposed from the first intermediate portions 533 of the pair of first side surfaces 53.

As shown in FIGS. 3 to 5, the pair of second side surfaces 54 are connected to the top surface 51 and the bottom surface 52, and are spaced apart from each other in the second direction y. As shown in FIG. 1, the first die pad 22, the second die pad 23, the first terminals 31, and the second terminals 32 are spaced apart from the pair of second side surfaces 54.

As shown in FIGS. 3 to 5, each of the pair of second side surfaces 54 includes a second upper portion 541, a second lower portion 542, and a second intermediate portion 543. One end of the second upper portion 541 in the thickness direction z is connected to the top surface 51, and the other end thereof in the thickness direction z is connected to the second intermediate portion 543. The second upper portion 541 is inclined relative to the top surface 51. One end of the second lower portion 542 in the thickness direction z is connected to the bottom surface 52, and the other end thereof in the thickness direction z is connected to the second intermediate portion 543. The second lower portion 542 is inclined relative to the bottom surface 52. One end of the second intermediate portion 543 in the thickness direction z is connected to the second upper portion 541, and the other end thereof in the thickness direction z is connected to the second lower portion 542. The in-plane direction of the second intermediate portion 543 is defined by the thickness direction z and the second direction y. As viewed in the thickness direction z, the second intermediate portion 543 is located more outward than the top surface 52 and the bottom surface 52.

As shown in FIGS. 6 and 7, the sealing resin 50 includes a first portion 50A and a second portion 50B. The first portion 50A covers the first semiconductor element 11, the second semiconductor element 12, and the insulating element 13. In the present embodiment, the first portion 50A covers the first wires 41, the second wires 42, the third wires 43, and the fourth wires 44. Furthermore, in the present embodiment, the first portion 50A covers the first pad portion 221 and the second pad portion 231. In the present example, the surface of the first portion 50A is smooth. The first portion 50A is formed by die molding, for example.

The second portion 50B constitutes the outermost surface of the sealing resin 50. In the present embodiment, the second portion 50B constitutes the top surface 51, the bottom surface 52, the pair of first side surfaces 53, and the pair of second side surfaces 54. The second portion 50B covers the first portion 50A. In the present embodiment, the second portion 50B is in contact with the first portion 50A. The second portion 50B may be formed by die molding after the first portion 50A is formed.

As compared to the first portion 50A, the second portion 50B is less prone to a tracking phenomenon. The tracking phenomenon is a phenomenon in which a carbonized conduction path is formed on the surface (or the inside) of a resin molded product due to, for example, an interaction between an electric field and an electrolyte contamination. In the present disclosure, the probability of the occurrence of a tracking phenomenon is evaluated by testing whether the resin molded product undergoes an electrical breakdown under a predetermined condition. Specifically, a pair of electrodes are brought into contact with the resin surface, and an electrolyte (NH₄Cl) is dropped onto a portion of the resin surface located between the pair of electrodes while voltage is applied. If an electrical breakdown occurs as a result of the test, it is evaluated that the probability of the occurrence of a tracking phenomenon is relatively high. On the other hand, if an electrical breakdown does not occur, it is evaluated that the probability of the occurrence of a tracking phenomenon is relatively low. Examples of standards for this evaluation method include ASTM D3638, IEC 60112, and JIS C 2134. The second portion 50B in the present embodiment can have a comparative tracking index (CTI) of 600 V or higher. Various specific examples can be cited as a configuration with which the second portion 50B is less prone to a tracking phenomenon than the first portion 50A. In the example shown in FIG. 8, the first portion 50A includes a first resin portion 501A and a plurality of first fillers 502A, and the second portion 50B includes a second resin portion 501B and a plurality of second fillers 502B. In the present embodiment, the “plurality of fillers” refer to a plurality of insulating fine pieces (described below). Each of the first resin portion 501A and the second resin portion 501B contains an insulating resin such as an epoxy resin or a synthetic resin. The first resin portion 501A and the second resin portion 501B may contain the same resin or different resins. The present example will be described with an assumption that the first resin portion 501A and the second resin portion 501B are both made of an epoxy resin. The first fillers 502A and the second fillers 502B are insulating fine pieces, and may contain at least one of silicon oxide (SiO₂) and alumina (Al₂O₃). The first fillers 502A and the second fillers 502B may contain the same material or different materials. The present example will be described with an assumption that the first fillers 502A and the second fillers 502B are each made of silicon oxide (SiO₂).

The content percentage of the second fillers 502B in the second portion 50B is higher than the content percentage of the first fillers 502A in the first portion 50A. This is one example of a specific configuration in which the second portion 50B is less prone to a tracking phenomenon than the first portion 50A. For example, the content percentage of the second fillers 502B in the second portion 50B may be 85 w % to 95 w %, and the content percentage of the first fillers 502A in the first portion 50A may be 80 w % to 90 w %.

As shown in FIG. 6, the second portion 50B covers the entirety of the first portion 50A. In other words, the first portion 50A is not exposed to the outside of the semiconductor device A1. To give numerical examples of the sealing resin 50, the first portion 50A, and the second portion 50B in the thickness direction z, when a thickness to of the sealing resin 50 is 1.5 mm to 3.0 mm, a thickness t1 of the first portion 50A is 1.5 mm to 2.9 mm, and a thickness t2 of the second portion 50B is 0.05 mm to 0.75 mm.

The configuration in which the second portion 50B is less prone to a tracking phenomenon than the first portion 50A is not limited to the specific configuration in which the content percentages of the first fillers 502A and the second fillers 502B are selected to have the above-described relationship. For example, the second portion 50B may be made of a low viscosity (LV) resin having a low melting point and a low molecular weight or a dicyclopentadiene (DCPD) resin having an alicyclic structure.

The second portion 50B is required to insulate the first semiconductor element 11, the second semiconductor element 12, the insulating element 13, the conductive members 20, the first wires 41, the second wires 42, the third wires 43, and the fourth wires 44 from each other. Furthermore, the second portion 50B is preferably resistant to peeling from the conductive members 20, etc., when the semiconductor device A1 is used. To provide such characteristics, the second portion 50B may be formed with use of a high-dielectric strength resin (e.g., a resin with a comparative tracking index (CTI) of 600V) that has a higher breakdown voltage than the first portion 50A. It is also possible to form the second portion 50B with use of a highly adhesive resin, such as a multi aromatic resin (MAR) or a biphenyl resin, so as to prevent the second portion 50B from peeling. As another strategy for the prevention of peeling, the second portion 50B may be formed with use of a low elasticity resin (e.g., a resin having a modulus of elasticity of no greater than 1000 MPa at 260° C.) or a high glass transition point resin (e.g., a resin having a glass transition point of at least 150° C.). Furthermore, the second portion 50B may be formed with use of a chlorine-free resin (e.g., an epoxy resin having a chlorine concentration of no greater than 30 ppm) or a sulfur-free resin (e.g., a resin having a sulfur concentration of no greater than 300 μg/g) so as to improve the characteristics described above.

A motor driver circuit for an inverter is typically configured with a half-bridge circuit including a low-side (low-potential-side) switching element and a high-side (high-potential-side) switching element. The following description is provided with an assumption that these switching elements are MOSFETs. Note that the reference potential of the source of the low-side switching element and the reference potential of the gate driver for driving the low-side switching element are both ground. On the other hand, the reference potential of the source of the high-side switching element and the reference potential of the gate driver for driving the high-side switching element both correspond to a potential at an output node of the half-bridge circuit. Because the potential at the output node varies according to the drive of the high-side switching element and the low-side switching element, the reference potential of the gate driver for driving the high-side switching element varies as well. When the high-side switching element is on, the reference potential is equivalent to the voltage applied to the drain of the high-side switching element (e.g., 600 V or higher). In the semiconductor device A1, the ground of the first semiconductor element 11 is spaced apart from the ground of the second semiconductor element 12. Accordingly, in the case where the semiconductor device A1 is used as the gate driver for driving the high-side switching element, a voltage equivalent to the voltage applied to the drain of the high-side switching element is transiently applied to the ground of the second semiconductor element 12.

The following describes advantages of the semiconductor device A1.

According to the present embodiment, the second portion 50B constitutes the outermost surface of the sealing resin 50. The second portion 50B is less prone to a tracking phenomenon than the first portion 50A. This makes it possible to suppress the occurrence of an unintentional electrical breakdown at the outermost surface of the semiconductor device A1 when, for example, the semiconductor device A1 is used. As a result, the semiconductor device A1 can perform its functions more appropriately. Furthermore, it is possible to improve the dielectric strength of the first portion 50A and prevent peeling while suppressing a tracking phenomenon at the second portion 50B.

The content percentage of the second fillers 502B in the second portion 50B is higher than the content percentage of the first fillers 502A in the first portion 50A. This makes it possible to suppress the occurrence of a tracking phenomenon in the second portion 50B more reliably than in the first portion 50A. It is suitable for suppressing a tracking phenomenon when the content percentage of the second fillers 502B is 85 w % to 95 w %. The configuration in which the content percentage of the first fillers 502A is different from that of the second fillers 502B is suitable for selectively suppressing a tracking phenomenon at the second portion 50B.

The second fillers 502B containing at least one of silicon oxide (SiO₂) and alumina (Al₂O₃) can increase the dielectric strength while suppressing a tracking phenomenon at the second portion 50B. The first fillers 502A containing at least one of silicon oxide (SiO₂) and alumina (Al₂O₃) can increase the dielectric strength of the first portion 50A.

FIGS. 9 to 16 show variations and other embodiments of the present disclosure. In these figures, elements that are the same as or similar to those in the above embodiment are provided with the same reference signs.

### First Variation of the First Embodiment

FIG. 9 shows a first variation of the semiconductor device A1. In a semiconductor device A11 of the present variation, the first portion 50A has an irregular portion 503A.

The irregular portion 503A is provided at a surface of the first portion 50A, and includes recesses and protrusions. The irregular portion 503A of the present example is formed by providing an area having recesses and protrusions for a predetermined portion of a mold for forming the first portion 50A, for example. When the irregular portion 503A is formed by providing a mold with an area having recesses and protrusions, the irregular portion 503A may be arranged only at each side of the first portion 50A in the thickness direction z. In this way, the mold can be removed more smoothly after the first portion 50A is formed.

The second portion 50B is in contact with the irregular portion 503A of the first portion 50A. In other words, the recesses of the irregular portion 503A are filled with the second portion 50B. It can also be said that the second portion 50B are formed with an irregular portion corresponding to the irregular portion 503A.

The present variation can also similarly allow the semiconductor device A11 to perform its functions more appropriately. Furthermore, the irregular portion 503A can suppress separation between the first portion 50A and the second portion 50B.

### Second Variation of the First Embodiment

FIG. 10 shows a second variation of the semiconductor device A1. A semiconductor device A12 according to the present variation is different from the semiconductor device A11 in the specific configuration of the irregular portion 503A.

The irregular portion 503A of the present variation is formed by subjecting the predetermined portion of the mold for forming the first portion 50A to an irregularity process, such as a matte finish process, that allows formation of recesses and protrusions much finer than the recesses and protrusions in the semiconductor device A11. The irregular portion 503A formed by the matte finish process has fine recesses and protrusions. If the recesses and protrusions of the irregular portion 503A are sufficiently fine, the irregular portion 503A may be formed over the entirety of the first portion 50A.

The present variation can also similarly allow the semiconductor device A12 to perform its functions more appropriately. Furthermore, as can be understood from the present variation, the irregular portion 503A is not particularly limited to a specific configuration.

### Second Embodiment

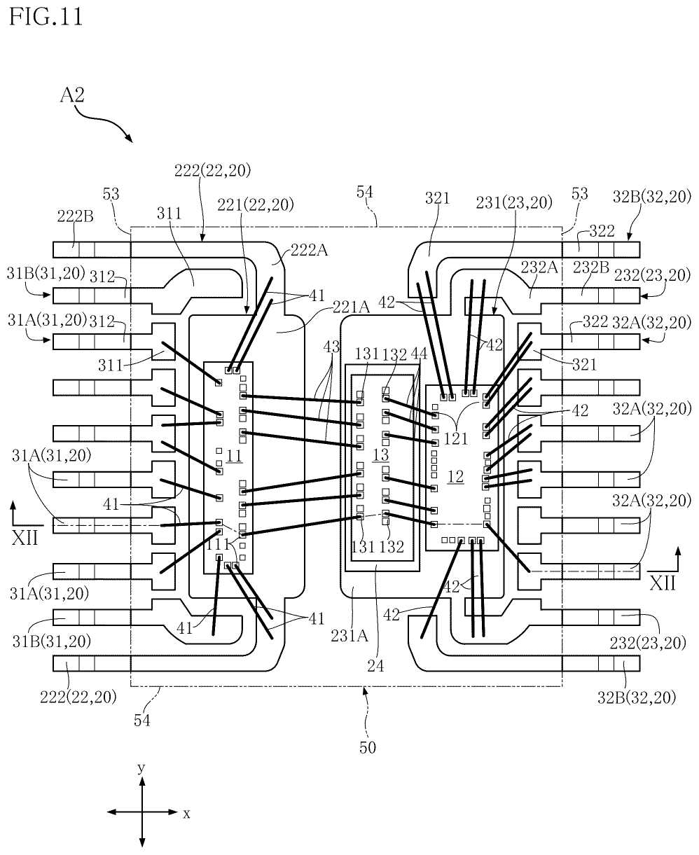

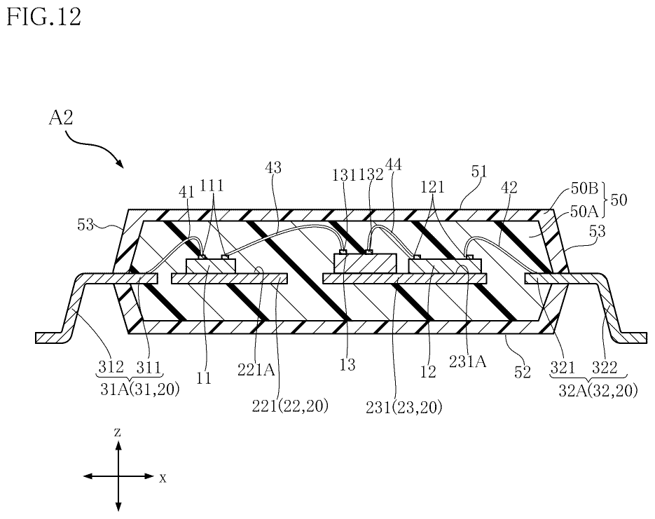

FIGS. 11 and 12 show a semiconductor device according to a second embodiment of the present disclosure. A semiconductor device A2 according to the present embodiment is different from the semiconductor device described in the above embodiment in the relationship between the insulating element 13 and the conductive members 20.

In the present embodiment, the insulating element 13 is mounted on the second pad portion 231 of the second die pad 23, together with the second semiconductor element 12. The insulating element 13 is aligned with the second semiconductor element 12 in the first direction x. The area of the second pad portion 231 is larger than the area of the first pad portion 221 of the first die pad 22.

The present embodiment can also allow the semiconductor device A2 to perform its functions more appropriately. As can be understood from the present embodiment, the arrangement, etc., of the first semiconductor element 11, the second semiconductor element 12, the insulating element 13, and the conductive members 20 are not particularly limited.

### Third Embodiment

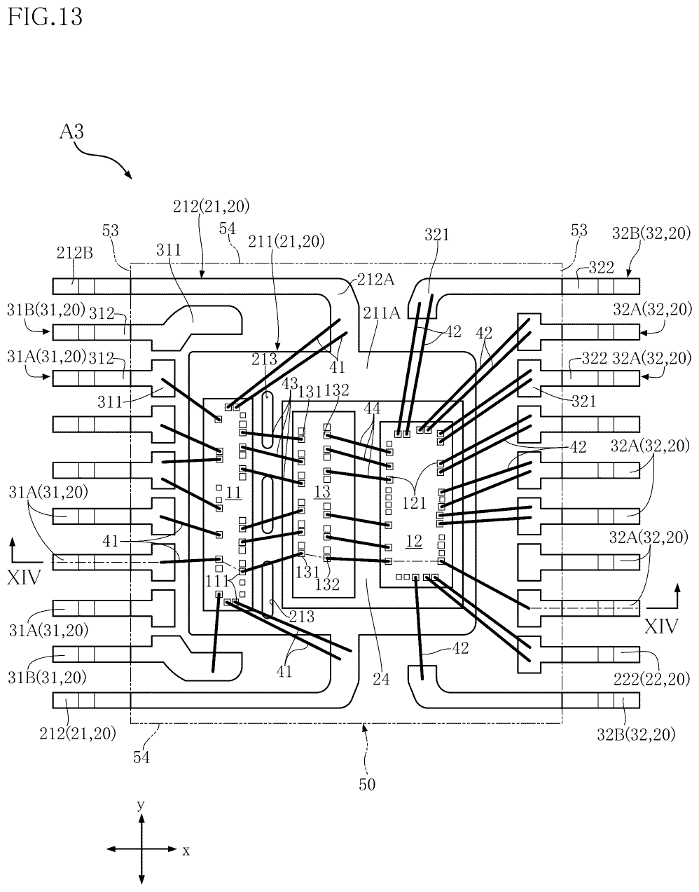

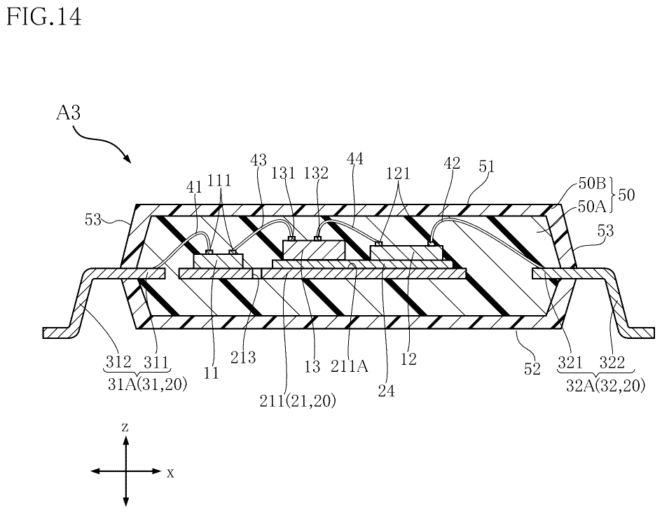

FIGS. 13 and 14 show a semiconductor device according to a third embodiment of the present disclosure. A semiconductor device A3 according to the present embodiment is different from the semiconductor devices described in the above embodiments in the relationship between each of the first semiconductor element 11, the second semiconductor element 12, and the insulating element 13 and each of the conductive members 20.

In the present embodiment, the conductive members 20 include a die pad 21. The die pad 21 has a pad portion 211 and two suspending lead portions 212. The first semiconductor element 11 and the second semiconductor element 12 are arranged on the pad portion 211. The pad portion 211 has a mounting surface 211A facing in the thickness direction z.

The pad portion 211 is covered with the sealing resin 50. The pad portion 211 has a thickness of about 150 μm to 200 μm, for example.

The pad portion 211 is formed with a plurality of through-holes 213. The through-holes 213 pass through the pad portion 211 in the thickness direction z and extend in the second direction y. As viewed in the thickness direction z, at least one of the through-holes 213 is located between the first semiconductor element 11 and the insulating substrate 24 described below. The through-holes 213 are aligned in the second direction y.

The two suspending lead portions 212 are connected to the respective sides of the pad portion 211 in the second direction y. Each of the two suspending lead portions 212 has a covered portion 212A and an exposed portion 212B. The covered portion 212A is connected to the pad portion 211 and covered with the sealing resin 50. The covered portion 212A includes a section extending in the first direction x. The exposed portion 212B is connected to the covered portion 212A and exposed from one of the pair of first side surfaces 53 of the sealing resin 50 from which the exposed portions 312 of the first terminals 31 are exposed. As viewed in the thickness direction z, the exposed portion 212B extends in the first direction x. The exposed portion 212B is bent into a gull-wing shape as viewed in the second direction y. The surface of the exposed portion 212B may be plated with tin, for example.

At least one of the first wires 41 is bonded to one of the first electrodes 111 of the first semiconductor element 11 and one of the covered portions 212A of the two suspending lead portions 212. As such, at least one of the two suspending lead portions 212 forms a ground terminal electrically connected to the first semiconductor element 11.

At least one of the second wires 42 is bonded to one of the second electrodes 121 of the second semiconductor element 12 and one of the covered portions 321 of the two second outer terminals 32B (second terminals 32). As such, at least one of the two second outer terminals 32B forms a ground terminal electrically connected to the second semiconductor element 12.

In the present embodiment, the first semiconductor element 11, the second semiconductor element 12, and the insulating element 13 are supported by the die pad 21. The first semiconductor element 11, the second semiconductor element 12, and the insulating element 13 overlap with the die pad 21 as viewed in the thickness direction z.

In the present embodiment, the first semiconductor element 11 is bonded to the mounting surface 211A via a non-illustrated conductive bonding member (e.g., solder or metal paste). The second semiconductor element 12 and the insulating element 13 are supported by the die pad 21 via the insulating substrate 24.

The insulating substrate 24 is bonded to the die pad 21. As viewed in the thickness direction z, the insulating substrate 24 is located inward from the periphery of the die pad 21. In the present embodiment, the insulating substrate 24 is bonded to the mounting surface 211A of the pad portion 211 of the die pad 21. The insulating substrate 24 is made of an insulating material containing alumina (Al₂O₃), for example. The insulating substrate 24 has a rectangular shape as viewed in the thickness direction z.

The insulating substrate 24 is bonded to the mounting surface 211A of the pad portion 211 by a bonding layer (not illustrated), for example. The bonding layer may contain an epoxy resin.

The second semiconductor element 12 is bonded to the insulating substrate 24 by a bonding layer (not illustrated), for example. The bonding layer may contain an epoxy resin.

The insulating element 13 is bonded to the insulating substrate 24 by a bonding layer (not illustrated), for example. The bonding layer may contain an epoxy resin.

The present embodiment can also allow the semiconductor device A3 to perform its functions more appropriately. As can be understood from the present embodiment, the semiconductor device of the present disclosure is not limited to the configuration in which the first semiconductor element 11 and the second semiconductor element 12 are supported by two pad portions that are spaced apart from each other. In the present embodiment, the second semiconductor element 12 and the insulating element 13 are supported by the pad portion 211 via the insulating substrate 24. This makes it possible to appropriately insulate the first semiconductor element 11 and the second semiconductor element 12 from each other.

### Fourth Embodiment

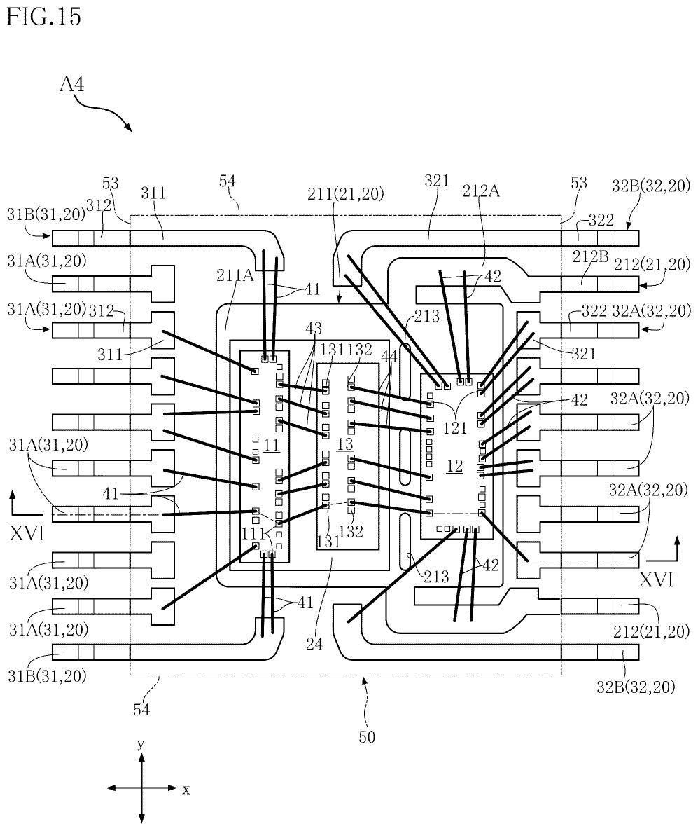

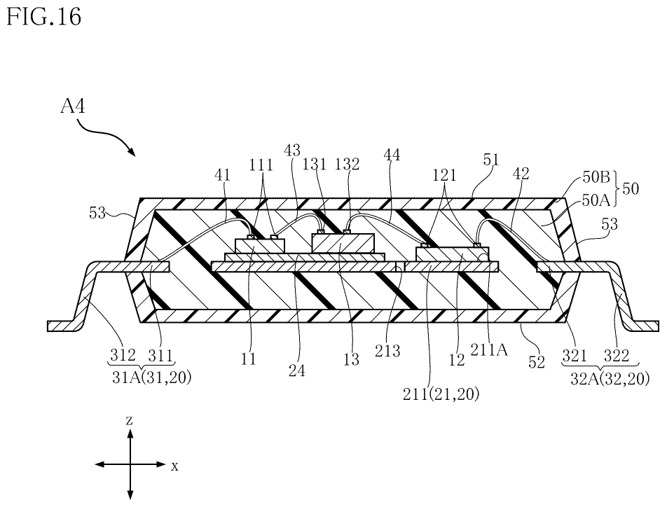

FIGS. 15 and 16 show a semiconductor device according to a fourth embodiment of the present disclosure. A semiconductor device A4 according to the present embodiment is different from the semiconductor devices described in the above embodiments in the relationship between each of the first semiconductor element 11, the second semiconductor element 12, and the insulating element 13 and each of the conductive members 20.

As with the semiconductor device A3 described above, the conductive members 20 include a die pad 21. The die pad 21 has a pad portion 211 and two suspending lead portions 212. The second semiconductor element 12 is bonded to the mounting surface 211A of the pad portion 211 via a non-illustrated conductive bonding member (e.g., solder or metal paste). As viewed in the thickness direction z, at least one of the through-holes 213 is located between the insulating substrate 24 and the second semiconductor element 12.

The exposed portions 212B of the two suspending lead portions 212 are exposed from one of the pair of first side surfaces 53 of the sealing resin 50 from which the exposed portions 322 of the second terminals 32 are exposed.

At least one of the first wires 41 is bonded to one of the first electrodes 111 of the first semiconductor element 11 and one of the covered portions 311 of the two first outer terminals 31B (first terminals 31). As such, at least one of the two first outer terminals 31B forms a ground terminal electrically connected to the first semiconductor element 11.

The first semiconductor element 11 is bonded to the insulating substrate 24. As with the second semiconductor element 12 of the semiconductor device A3, the first semiconductor element 11 is bonded to the insulating substrate 24 by a bonding layer (not illustrated). Thus, in the semiconductor device A4, the insulating substrate 24 is interposed between the die pad 21 and each of the first semiconductor element 11 and the insulating element 13, and the first semiconductor element 11 and the insulating element 13 are bonded to the insulating substrate 24. Furthermore, as viewed in the thickness direction z, the third wires 43 are located inward from a periphery 241 of the insulating substrate 24.

At least one of the second wires 42 is bonded to one of the second electrodes 121 of the second semiconductor element 12 and one of the covered portions 212A of the two suspending lead portions 212. As such, at least one of the two suspending ground terminal electrically lead portions 212 forms a connected to the second semiconductor element 12.

The present embodiment can also allow the semiconductor device A4 to perform its functions more appropriately. In the present embodiment, the first semiconductor element 11 and the insulating element 13 are supported by the pad portion 211 via the insulating substrate 24. This makes it possible to insulate the first semiconductor element 11 and the second semiconductor element 12 from each other appropriately.

The semiconductor device according to the present disclosure is not limited to the above embodiments. Various design changes can be made to the specific configurations of the elements of the semiconductor device according to the present disclosure. The present disclosure includes the embodiments described in the following clauses.

### Clause 1.

A semiconductor device comprising:
a first semiconductor element;
a second semiconductor element;
an insulating element electrically connected to the first semiconductor element and the second semiconductor element, and insulating the first semiconductor element and the second semiconductor element from each other; and
a sealing resin covering the first semiconductor element, the second semiconductor element, and the insulating element,
wherein the sealing resin includes a first portion covering semiconductor element, the second the first semiconductor element, and the insulating element, and a second portion constituting an outermost surface of the sealing resin, and
the second portion is less prone to a tracking phenomenon than the first portion.

### Clause 2.

The semiconductor device according to clause 1, wherein the first portion includes a first resin portion and a plurality of first fillers,
the second portion includes a second resin portion and a plurality of second fillers, and
a content percentage of the second fillers in the second portion is higher than a content percentage of the first fillers in the first portion.

### Clause 3.

The semiconductor device according to clause 2, wherein the second fillers contain at least one of silicon oxide (SiO₂) and alumina (Al₂O₃).

### Clause 4.

The semiconductor device according to clause 2 or 3, wherein the first fillers contain at least one of silicon oxide (SiO₂) and alumina (Al₂O₃).

### Clause 5.

The semiconductor device according to clause 4, wherein the first fillers and the second fillers contain silicon oxide (SiO₂).

### Clause 6.

The semiconductor device according to any of clauses 1 to 5, wherein the second portion contains a low viscosity (LV) resin having a low melting point and a low molecular weight or a dicyclopentadiene (DCPD) resin having an alicyclic structure.

### Clause 7.

The semiconductor device according to any of clauses 1 to 6, wherein the first portion includes an irregular portion, and the second portion is in contact with the irregular portion.

### Clause 8.

The semiconductor device according to any of clauses 1 to 7, further comprising a conductive member electrically connected to the first semiconductor element and the second semiconductor element,
wherein the conductive member includes a first die pad and a second die pad spaced apart from each other,
the first die pad and the second die pad are insulated from each other via the first portion,
the first semiconductor element is supported by the first die pad, and
the second semiconductor element is supported by the second die pad.

### Clause 9.

The semiconductor device according to clause 8, wherein the insulating element is supported by the first die pad.

### Clause 10.

The semiconductor device according to clause 8, wherein the insulating element is supported by the second die pad.

### Clause 11.

The semiconductor device according to any of clauses 1 to 7, further comprising a conductive member electrically connected to the first semiconductor element and the second semiconductor element,
wherein the conductive member includes a die pad, and
the first semiconductor element, the second semiconductor element, and the insulating element are supported by the die pad.

### Clause 12.

The semiconductor device according to clause 11, wherein the second semiconductor element and the insulating element are supported by the die pad via an insulating substrate.

### Clause 13.

The semiconductor device according to clause 11, wherein the first semiconductor element and the insulating element are supported by the die pad via an insulating substrate.

### Clause 14.

The semiconductor device according to any of clauses 8 to 13, comprising:
a first wire connected to the first semiconductor element and the conductive member; and
a second wire connected to the second semiconductor element and the conductive member,
wherein the first wire and the second wire are covered with the first portion.

### Clause 15.

The semiconductor device according to clause 14, comprising:
a third wire connected to the first semiconductor element and the insulating element; and
a fourth wire connected to the second semiconductor element and the insulating element,
wherein the third wire and the fourth wire are covered with the first portion.

### Clause 16.

The semiconductor device according to any of clauses 1 to 15, wherein the insulating element is located between the first semiconductor element and the second semiconductor element in a first direction.

### Clause 17.

The semiconductor device according to any of clauses 1 to 16, wherein the insulating element is either of an inductive type or a capacitive type.

REFERENCE NUMERALS

| | |
|---|---|
| A1, A11, A12, A2, A3, A4: | |
| Semiconductor device | |
| 11: First semiconductor element | |
| 12: Second semiconductor element | |
| 13: Insulating element | 20: Conductive member |
| 21: Die pad | 22: First die pad |
| 23: Second die pad | 24: Insulating substrate |
| 31: First terminal | 31A: First inner terminal |
| 31B: First outer terminal | 32: Second terminal |
| 32A: Second inner terminal | 32B: Second outer terminal |
| 41: First wire | 42: Second wire |
| 43: Third wire | 44: Fourth wire |
| 50: Sealing resin | 50A: First portion |
| 50B: Second portion | 51: Top surface |
| 52: Bottom surface | 53: First side surface |
| 54: Second side surface | 111: First electrode |
| 121: Second electrode | 131: First relay electrode |
| 132: Second relay electrode | 211: Pad portion |
| 211A: Mounting surface | 212: Suspending lead portion |
| 212A: Covered portion | 212B: Exposed portion |
| 213: Through-hole | 221: First pad portion |
| 221A: First mounting surface | |
| 222: First suspending lead portion | |
| 222A: Covered portion | 222B: Exposed portion |
| 223: Through-hole | 231: Second pad portion |
| 231A: Second mounting surface | |
| 232: Second suspending lead portion | |
| 232A: Covered portion | 232B: Exposed portion |
| 241: Periphery | 311: Covered portion |
| 312: Exposed portion | 321: Covered portion |
| 322: Exposed portion | 501A: First resin portion |
| 501B: Second resin portion | 502A: First filler |
| 502B: Second filler | 503A: Irregular portion |
| 531: First upper portion | 532: First lower portion |
| 533: First intermediate portion | 541: Second upper portion |
| 542: Second lower portion | 543: Second intermediate portion |
| t0, t1, t2: Thickness | x: First direction |
| y: Second direction | z: Thickness direction |

1. A semiconductor device comprising:
a first semiconductor element;
a second semiconductor element;
an insulating element electrically connected to the first semiconductor element and the second semiconductor element, and insulating the first semiconductor element and the second semiconductor element from each other; and
a sealing resin covering the first semiconductor element, the second semiconductor element, and the insulating element,
wherein the sealing resin includes a first portion covering the first semiconductor element, the second semiconductor element, and the insulating element, and a second portion constituting an outermost surface of the sealing resin, and
the second portion is less prone to a tracking phenomenon than the first portion.

2. The semiconductor device according to claim 1,
wherein the first portion includes a first resin portion and a plurality of first fillers,
the second portion includes a second resin portion and a plurality of second fillers, and
a content percentage of the second fillers in the second portion is higher than a content percentage of the first fillers in the first portion.

3. The semiconductor device according to claim 2, wherein the second fillers contain at least one of silicon oxide (SiO₂) and alumina (Al₂O₃).

4. The semiconductor device according to claim 2, wherein the first fillers contain at least one of silicon oxide (SiO₂) and alumina (Al₂O₃).

5. The semiconductor device according to claim 4, wherein the first fillers and the second fillers contain silicon oxide (SiO₂).

6. The semiconductor device according to claim 1, wherein the second portion contains a low viscosity (LV) resin having a low melting point and a low molecular weight or a dicyclopentadiene (DCPD) resin having an alicyclic structure.

7. The semiconductor device according to claim 1,
wherein the first portion includes an irregular portion, and
the second portion is in contact with the irregular portion.

8. The semiconductor device according to claim 1, further comprising a conductive member electrically connected to the first semiconductor element and the second semiconductor element,
wherein the conductive member includes a first die pad and a second die pad spaced apart from each other,
the first die pad and the second die pad are insulated from each other via the first portion,
the first semiconductor element is supported by the first die pad, and
the second semiconductor element is supported by the second die pad.

9. The semiconductor device according to claim 8, wherein the insulating element is supported by the first die pad.

10. The semiconductor device according to claim 8, wherein the insulating element is supported by the second die pad.

11. The semiconductor device according to claim 1, further comprising a conductive member electrically connected to the first semiconductor element and the second semiconductor element,
the conductive member includes a die pad, and
the first semiconductor element, the second semiconductor element, and the insulating element are supported by the die pad.

12. The semiconductor device according to claim 11, wherein the second semiconductor element and the insulating element are supported by the die pad via an insulating substrate.

13. The semiconductor device according to claim 11, wherein the first semiconductor element and the insulating element are supported by the die pad via an insulating substrate.

14. The semiconductor device according to claim 8, comprising:
a first wire connected to the first semiconductor element and the conductive member; and
a second wire connected to the second semiconductor element and the conductive member,
wherein the first wire and the second wire are covered with the first portion.

15. The semiconductor device according to claim 14, comprising:
a third wire connected to the first semiconductor element and the insulating element; and
a fourth wire connected to the second semiconductor element and the insulating element,
wherein the third wire and the fourth wire are covered with the first portion.

16. The semiconductor device according to claim 1, wherein the insulating element is located between the first semiconductor element and the second semiconductor element in a first direction.

17. The semiconductor device according to claim 1, wherein the insulating element is either of an inductive type or a capacitive type.
